(19) United States
(12) Patent Application Publication
(10) Pub. No.: US 2024/0096810 A1
(43) Pub. Date: Mar. 21, 2024

(54) Systems And Methods For Coupling Integrated Circuit Dies

(71) Applicant: Intel Corporation, Santa Clara, CA (US)

(72) Inventors: Md Altaf Hossain, Portland, OR (US); Mahesh Kumashikar, Bangalore (IN); Ankireddy Nalamalpu, Portland, OR (US)

(73) Assignee: Intel Corporation, Santa Clara, CA (US)

(21) Appl. No.: 18/206,840

(22) Filed: Jun. 7, 2023

(51) Int. Cl. H01L 23/538; H01L 25/065

(52) U.S. Cl. CPC H01L 23/5386; H01L 25/0652; H01L 24/16; H01L 2224/16145; H01L 2224/16225

(57) ABSTRACT

A circuit system includes a support device having an interconnection conductor. The circuit system also includes first, second, and third integrated circuits that are mounted on the support device. The interconnection conductor couples the first integrated circuit to the third integrated circuit. The second integrated circuit is between the first integrated circuit and the third integrated circuit.

### TECHNICAL FIELD

The present disclosure relates to electronic circuit systems and methods, and more particularly, to circuit systems and methods for coupling integrated circuit dies.

### BACKGROUND ART

Many modern electronic circuit systems include integrated circuit (IC) packages. An integrated circuit (IC) package may contain multiple integrated circuit dies. The integrated circuit dies in an IC package may, for example, be mounted on an interposer or a package substrate.

### BRIEF DESCRIPTION OF DRAWINGS

FIG. 1 is a diagram that illustrates a top down view of an example of a circuit system that includes a support device and 16 integrated circuit dies.

FIG. 2 is a diagram that illustrates a top down view of the circuit system of Figure (FIG. 1 with additional vertical conductors in the support device.

FIG. 3 is a diagram that illustrates a top down view of the circuit system of FIG. 1 with additional conductors that are routed vertically and horizontally in the support device.

FIG. 4 is a diagram that illustrates a top down view of the circuit system of FIG. 1 with additional conductors that are routed diagonally in the support device.

FIG. 5 is a diagram that illustrates a side view of an example of a circuit system, or a portion thereof, that includes five integrated circuits and a support device.

FIG. 6 is a diagram that illustrates a side view of an example of a circuit system, or a portion thereof, that includes six integrated circuits and a support device.

FIG. 7 is a diagram of an illustrative example of a programmable integrated circuit (IC) that can be any one or more of the ICs shown in FIGS. 1-6.

### DETAILED DESCRIPTION

Some electronic circuit systems include multiple integrated circuits (ICs) in the same package. As an example, two, three, four, or more ICs can be housed in the same package. The integrated circuits in the package can, for example, be coupled together through a package substrate or interposer in the package. As another example, two integrated circuits can be stacked vertically and coupled together in a 3-dimensional (3D) arrangement. A single integrated circuit (IC) package can, for example, be designed to house processing ICs and transceiver ICs that implement data transmission protocols for communications between the processing ICs and one or more devices external to the IC package. Some IC packages include interconnection bridges. However, interconnections bridges only couple together ICs that are adjacent to each other in the IC package.

According to some examples disclosed herein, two or more non-adjacent integrated circuits in a circuit system are coupled together through interconnection conductors in a support device. The circuit system includes the support device and first, second, and third integrated circuits. The circuit system can be, for example, an integrated circuit package. The support device can be, for example, a package substrate or an interposer. An interconnection conductor in the support device couples the first integrated circuit device to the third integrated circuit device. The second integrated circuit is between the first and the third integrated circuits. The interconnection conductor can be routed around the second integrated circuit (e.g., under, over, or next to the second integrated circuit), depending on the orientation of the support device relative to the integrated circuits. Thus, the interconnection conductor provides an electrical pathway for signals to be routed between the first and third integrated circuits that are not adjacent to each other in the circuit system. As examples, the interconnection conductor can be routed horizontally, vertically, diagonally, or in a stepped configuration through the support device relative to an orientation of the support device in the circuit system.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

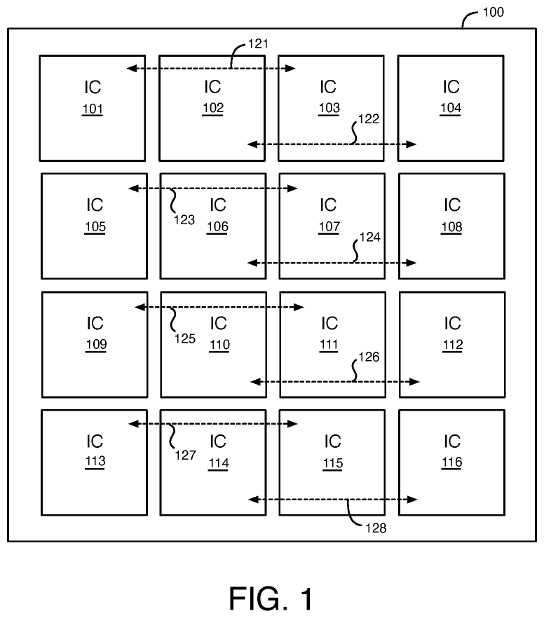

FIG. 1 is a diagram that illustrates a top down view of an example of a circuit system that includes a support device 100 and 16 integrated circuits 101-116. Each of the integrated circuits (ICs) 101-116 is an individual integrated circuit (IC) die that is mounted on, and coupled to, the support device 100. ICs 101-116 are arranged in a 4×4 array in the example of FIG. 1, with ICs 101, 104, 113, and 116 being in the 4 corners of the array. Although 16 dies arranged in a 4×4 array are shown in FIG. 1, it should be understood that the techniques disclosed herein can be used in circuit systems having any suitable number of ICs that are arranged in any suitable configuration. Each of the ICs 101-116 can be any type of IC, such as a programmable logic IC, a microprocessor IC, a graphics processing unit IC, a memory IC, an application specific IC, a transceiver IC, a memory IC, etc. The circuit system of FIG. 1 can be, for example, an integrated circuit (IC) package. As examples, the support device 100 can be a package substrate or an interposer.

The support device 100 includes 8 interconnection conductors 121-128 that are routed horizontally with respect to the orientation shown in FIG. 1. Support device 100 may also be referred to as an interconnection device. Interconnection conductor 121 couples integrated circuit (IC) 101 and IC 103. Interconnection conductor 121 can route signals between ICs 101 and 103. Interconnection conductor 121 is routed under IC 102. IC 102 is between ICs 101 and 103. Interconnection conductor 122 couples IC 102 and IC 104. Interconnection conductor 122 can route signals between ICs 102 and 104. Interconnection conductor 122 is routed under IC 103. IC 103 is between ICs 102 and 104.

Interconnection conductor 123 couples integrated circuit (IC) 105 and IC 107. Interconnection conductor 123 can route signals between ICs 105 and 107. Interconnection conductor 123 is routed under IC 106. IC 106 is between ICs 105 and 107. Interconnection conductor 124 couples IC 106 and IC 108. Interconnection conductor 124 can route signals between ICs 106 and 108. Interconnection conductor 124 is routed under IC 107. IC 107 is between ICs 106 and 108.

Interconnection conductors 125, 126, 127, and 128 couple (and can route signals between) ICs 109 and 111, ICs 110 and 112, ICs 113 and 115, and ICs 114 and 116, respectively. Interconnection conductors 125, 126, 127, and 128 are routed under ICs 110, 111, 114, and 115, respectively. ICs 110, 111, 114, and 115 are between ICs 109 and 111, ICs 110 and 112, ICs 113 and 115, and ICs 114 and 116, respectively.

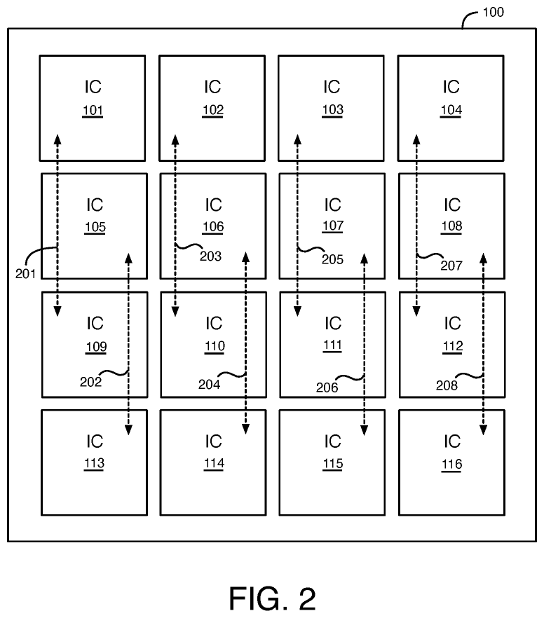

FIG. 2 is a diagram that illustrates a top down view of the circuit system of FIG. 1 with additional vertical conductors in the support device 100. In the example of FIG. 2, the support device 100 includes 8 additional interconnection conductors 201-208 that are routed vertically with respect to the orientation shown in FIG. 2. Interconnection conductor 201 couples integrated circuit (IC) 101 and IC 109. Interconnection conductor 201 can route signals between ICs 101 and 109. Interconnection conductor 201 is routed under IC 105. IC 105 is between ICs 101 and 109. Interconnection conductor 202 couples integrated circuits (ICs) 105 and 113. Interconnection conductor 202 can route signals directly between ICs 105 and 113. Interconnection conductor 202 is routed under IC 109. IC 109 is between ICs 105 and 113. Interconnection conductors 203, 204, 205, 206, 207, and 208 couple (and can route signals between) ICs 102 and 110, ICs 106 and 114, ICs 103 and 111, ICs 107 and 115, ICs 104 and 112, and ICs 108 and 116, respectively. Interconnection conductors 203, 204, 205, 206, 207, and 208 are routed under ICs 106, 110, 107, 111, 108, and 112, respectively. ICs 106, 110, 107, 111, 108, and 112 are between ICs 102 and 110, ICs 106 and 114, ICs 103 and 111, ICs 107 and 115, ICs 104 and 112, and ICs 108 and 116, respectively.

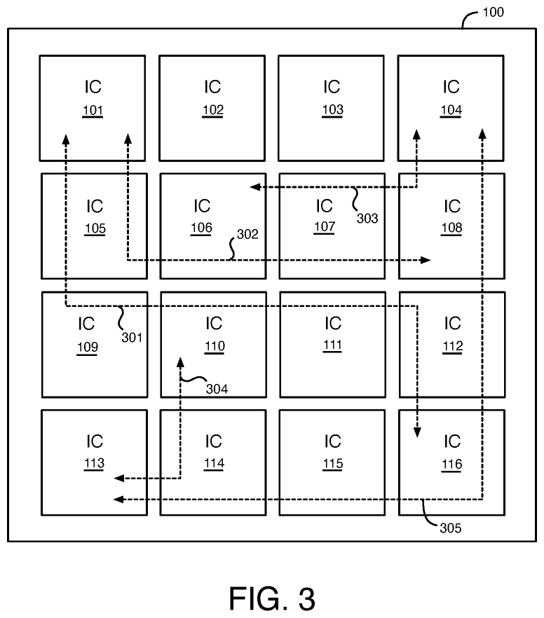

FIG. 3 is a diagram that illustrates a top down view of the circuit system of FIG. 1 with additional conductors that are routed vertically and horizontally in the support device 100. In the example of FIG. 3, the support device 100 includes 5 additional interconnection conductors 301-305 that are each routed vertically and horizontally with respect to the orientation shown in FIG. 3. Each of the interconnection conductors 301-305 includes a right angle (90 degree) turn in the top down view of FIG. 3. Conductor 301 includes two right angle turns in the top down view of FIG. 3.

Interconnection conductor 301 couples together ICs 101 and 116. Interconnection conductor 301 can route signals between ICs 101 and 116. Interconnection conductor 301 is routed under ICs 105 and 109-112. ICs 105 and 109-112 are between ICs 101 and 116 in the circuit system.

Interconnection conductor 302 couples together, and routes signals between, ICs 101 and 108. Interconnection conductor 302 is routed under ICs 105-107. ICs 105-107 are between ICs 101 and 108 in the circuit system.

Interconnection conductors 303, 304, and 305 couple together, and route signals between, ICs 104 and 106, ICs 110 and 113, and 104 and 113, respectively. Interconnection conductors 303, 304, and 305 are routed under ICs 107-108, IC 114, and ICs 108, 112, and 114-116, respectively. ICs 107-108 are between ICs 104 and 106. IC 114 is between ICs 110 and 113. ICs 108, 112, and 114-116 are between ICs 104 and 113 in the circuit system.

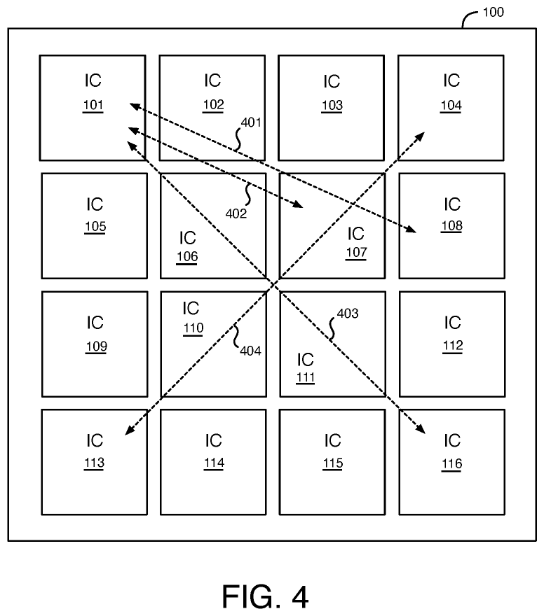

FIG. 4 is a diagram that illustrates a top down view of the circuit system of FIG. 1 with additional conductors that are routed diagonally in the support device 100. In the example of FIG. 4, the support device 100 includes 4 additional interconnection conductors 401-404 that are each routed diagonally with respect to the orientation shown in FIG. 4. Each of the interconnection conductors 401-404 is routed diagonally with respect to each of the 4 sides of device 100.

Interconnection conductor 401 couples, and routes signals between, ICs 101 and 108. Interconnection conductor 401 is routed under ICs 102 and 107. ICs 102 and 107 are between ICs 101 and 108 in the circuit system. Interconnection conductor 402 couples, and routes signals between, ICs 101 and 107. Interconnection conductor 402 is routed under ICs 102 and 106. ICs 102 and 106 are between ICs 101 and 107 in the circuit system. Interconnection conductor 403 couples, and routes signals between, ICs 101 and 116. Interconnection conductor 403 is routed under ICs 106 and 111. ICs 106 and 111 are between ICs 101 and 116 in the circuit system. Interconnection conductor 404 couples, and routes signals between, ICs 104 and 113. Interconnection conductor 404 is routed under ICs 107 and 110. ICs 107 and 110 are between ICs 104 and 113 in the circuit system.

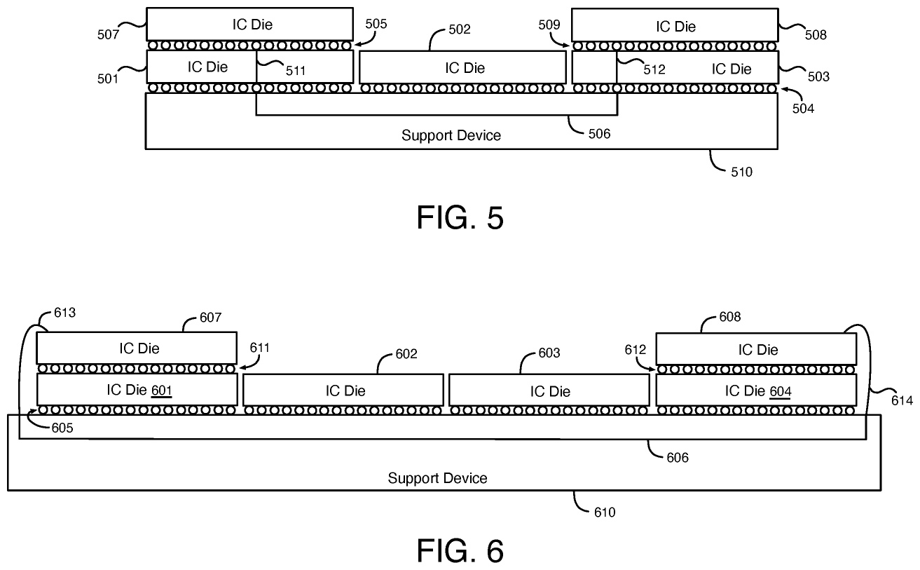

FIG. 5 is a diagram that illustrates a side view of an example of a circuit system, or a portion thereof, that includes five integrated circuits (ICs) 501-503 and 507-508 and a support device 510. FIG. 5 can, for example, be an illustration of a portion of the circuit system of any one or more of FIGS. 1-4 that shows three of the 16 ICs 101-116 as ICs 501-503 and 507-508, and in which support device 510 is a portion of support device 100. Each of the ICs 501, 502, and 503 is coupled to and mounted on the support device 510 through a subset of conductive bumps 504. IC 507 is vertically stacked on top of IC 501 in a three-dimensional (3D) configuration, and IC 507 is coupled to IC 501 through conductive bumps 505. IC 508 is vertically stacked on top of IC 503 in a 3D configuration, and IC 508 is coupled to IC 503 through conductive bumps 509. In alternative implementations, some or all of the conductive bumps of FIG. 5 can be replaced with conductive pillars.

In the example of FIG. 5, an interconnection conductor 506 in the support device 510 couples integrated circuit (IC) 501 and IC 503 through two of the conductive bumps 504. One of these conductive bumps 504 connects IC 501 to conductor 506, and the second one of these conductive bumps 504 connects IC 503 to conductor 506. Signals can be transmitted between ICs 501 and 503 through these two conductive bumps and conductor 506. Conductor 506 includes two vertical portions and a horizontal portion, in the side view of FIG. 5. Interconnection conductor 506 is routed under IC 502. IC 502 is between ICs 501 and 503. Conductor 506 can be, for example, any one of conductors 121-128 or 201-208.

IC die 507 is coupled to conductor 506 through one of conductive bumps 505, conductive material in a through-silicon via 511 in IC 501, and one of the conductive bumps 504 under IC 501. IC die 508 is coupled to conductor 506 through one of conductive bumps 509, conductive material in a through-silicon via (TSV) 512 in IC 503, and one of the conductive bumps 504 under IC 503. Signals can be transmitted between ICs 507 and 508 through these conductive bumps, TSVs 511-512, and conductor 506 in support device 510.

FIG. 6 is a diagram that illustrates a side view of an example of a circuit system, or a portion thereof, that includes 6 integrated circuits 601-604 and 607-608 and a support device 610. FIG. 6 can, for example, be an illustration of a portion of the circuit system of any one or more of FIGS. 1-4 that shows 4 of the 16 ICs 101-116 as ICs 601-604, and in which support device 610 is a cross section of support device 100. Each of the ICs 601, 602, 603, and 604 is coupled to, and mounted on, the support device 610 through a subset of conductive bumps 605. IC 607 is vertically stacked on top of IC 601 in a three-dimensional (3D) configuration, and IC 607 is coupled to IC 601 through conductive bumps 611. IC 608 is vertically stacked on top of IC 604 in a 3D configuration, and IC 608 is coupled to IC 604 through conductive bumps 612. In alternative implementations, some or all of the conductive bumps of FIG. 6 can be replaced with conductive pillars.

In the example of FIG. 6, an interconnection conductor 606 in the support device 610 couples integrated circuit (IC) 607 and IC 608 through two wire bond connections 613-614. Wire bond connection 613 connects IC 607 to conductor 606 in the support device 610, and wire bond connection 614 connects IC 608 to conductor 606 in the support device 610. Signals can be transmitted between ICs 607 and 608 through these two wire bond connections 613-614 and conductor 606. Conductor 606 includes two vertical portions and a horizontal portion connecting the two vertical portions, in the side view of FIG. 6. Interconnection conductor 606 is routed under ICs 602-603. ICs 602-603 are between ICs 601 and 604. Conductor 606 can be, for example, any one of conductors 401, 403, or 404, if the circuit system if FIG. 4 includes vertically stacked ICs.

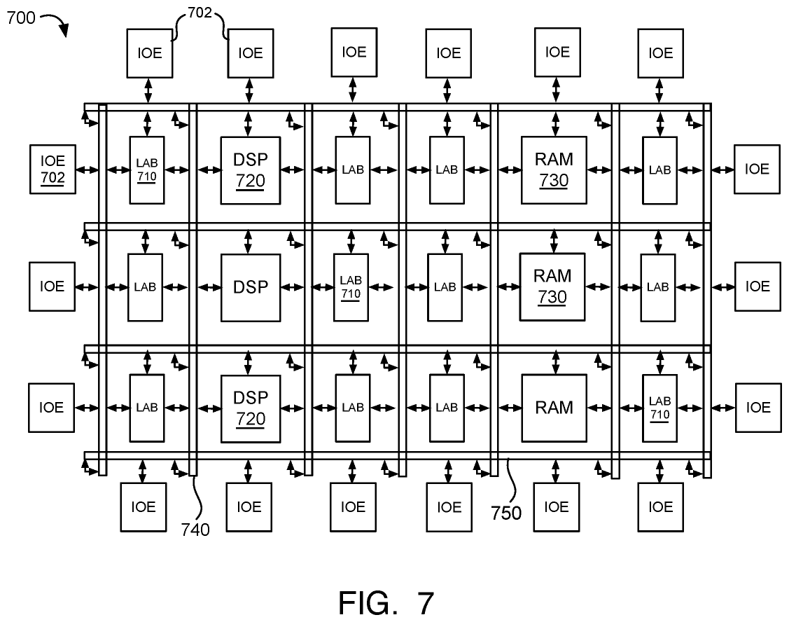

FIG. 7 is a diagram of an illustrative example of a programmable integrated circuit (IC) 700 that can be any one or more of the ICs shown in FIGS. 1-6. As shown in FIG. 7, the programmable integrated circuit 700 may include a two-dimensional array of functional blocks, including logic array blocks (LABs) 710 and other functional blocks, such as random access memory (RAM) blocks 730 and digital signal processing (DSP) blocks 720, for example. Functional blocks, such as LABs 710, may include smaller programmable regions (e.g., logic elements, configurable logic blocks, or adaptive logic modules) that receive input signals and perform custom functions on the input signals to produce output signals. One or more of the LABs 710 and/or DSPs 720 can implement the processing elements discussed above.

In addition, the programmable integrated circuit 700 may have input/output elements (IOEs) 702 for driving signals off of programmable integrated circuit 700 and for receiving signals from other devices. Input/output elements 702 may include parallel input/output circuitry, serial data transceiver circuitry, differential receiver and transmitter circuitry, or other circuitry used to connect one integrated circuit to another integrated circuit. As shown, input/output elements 702 may be located around the periphery of the IC. If desired, the programmable integrated circuit 700 may have input/output elements 702 arranged in different ways. For example, input/output elements 702 may form one or more columns of input/output elements that may be located anywhere on the programmable integrated circuit 700 (e.g., distributed evenly across the width of the programmable integrated circuit). If desired, input/output elements 702 may form one or more rows of input/output elements (e.g., distributed across the height of the programmable integrated circuit). Alternatively, input/output elements 702 may form islands of input/output elements that may be distributed over the surface of the programmable integrated circuit 700 or clustered in selected areas.

The programmable integrated circuit 700 may also include programmable interconnect circuitry in the form of vertical routing channels 740 (i.e., interconnects formed along a vertical axis of programmable integrated circuit 700) and horizontal routing channels 750 (i.e., interconnects formed along a horizontal axis of programmable integrated circuit 700), each routing channel including at least one track to route at least one wire.

Note that other routing topologies, besides the topology of the interconnect circuitry depicted in FIG. 7, may be used. For example, the routing topology may include wires that travel diagonally or that travel horizontally and vertically along different parts of their extent as well as wires that are perpendicular to the device plane in the case of three dimensional integrated circuits, and the driver of a wire may be located at a different point than one end of a wire. The routing topology may include global wires that span substantially all of programmable integrated circuit 700, fractional global wires such as wires that span part of programmable integrated circuit 700, staggered wires of a particular length, smaller local wires, or any other suitable interconnection resource arrangement.

Furthermore, it should be understood that examples disclosed herein may be implemented in any type of integrated circuit. If desired, the functional blocks of such an integrated circuit may be arranged in more levels or layers in which multiple functional blocks are interconnected to form still larger blocks. Other device arrangements may use functional blocks that are not arranged in rows and columns.

Programmable integrated circuit 700 may contain programmable memory elements. Memory elements may be loaded with configuration data (also called programming data) using input/output elements (IOEs) 702. Once loaded, the memory elements each provide a corresponding static control signal that controls the operation of an associated functional block (e.g., LABs 710, DSP 720, RAM 730, or input/output elements 702).

In a typical scenario, the outputs of the loaded memory elements are applied to the gates of field-effect transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, etc.

The memory elements may use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory or programmable memory elements.

The programmable memory elements may be organized in a configuration memory array consisting of rows and columns. A data register that spans across all columns and an address register that spans across all rows may receive configuration data. The configuration data may be shifted onto the data register. When the appropriate address register is asserted, the data register writes the configuration data to the configuration memory elements of the row that was designated by the address register.

Programmable integrated circuit 700 may include configuration memory that is organized in sectors, whereby a sector may include the configuration RAM bits that specify the function and/or interconnections of the subcomponents and wires in or crossing that sector. Each sector may include separate data and address registers.

The programmable IC of FIG. 7 is merely one example of an IC that can be used with embodiments disclosed herein. The embodiments disclosed herein can be used with any suitable integrated circuit or system. For example, the embodiments disclosed herein can be used with numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPGAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

Additional examples are now disclosed. Example 1 is a circuit system comprising: a support device comprising a first interconnection conductor; and first, second, and third integrated circuits that are coupled to the support device, wherein the first interconnection conductor couples the first integrated circuit to the third integrated circuit, and wherein the second integrated circuit is between the first integrated circuit and the third integrated circuit.

In Example 2, the circuit system of Example 1 further comprises: fourth and fifth integrated circuits that are coupled to the support device, wherein the support device further comprises a second interconnection conductor that couples the first integrated circuit to the fifth integrated circuit, and wherein the fourth integrated circuit is between the first integrated circuit and the fifth integrated circuit.

In Example 3, the circuit system of any one of Examples 1-2 may optionally include, wherein the support device comprises an interposer.

In Example 4, the circuit system of any one of Examples 1-3 may optionally include, wherein the circuit system is an integrated circuit package, and wherein the support device comprises a package substrate.

In Example 5, the circuit system of any one of Examples 1˜4 may optionally include, wherein the first interconnection conductor comprises a first portion that is routed at a right angle with respect to a second portion of the first interconnection conductor from a top down perspective of the circuit system.

In Example 6, the circuit system of any one of Examples 1-5 may optionally include, wherein the first interconnection conductor is routed diagonally with respect to an edge of the support device.

In Example 7, the circuit system of any one of Examples 1-6 may optionally include, wherein the first integrated circuit and the third integrated circuit are in two corners of an array of dies in the circuit system, and wherein the first interconnection conductor is at least part of a corner-to-corner connection between the first integrated circuit and the third integrated circuit.

In Example 8, the circuit system of any one of Examples 1-7 further comprises: a fourth integrated circuit mounted on the support device, wherein the first integrated circuit is vertically mounted above the fourth integrated circuit; and a fifth integrated circuit mounted on the support device, wherein the third integrated circuit is vertically mounted above the fifth integrated circuit.

Example 9 is a method comprising: transmitting a first signal through a first interconnection conductor in a support device from a first integrated circuit to a second integrated circuit; and transmitting a second signal through the first interconnection conductor from the second integrated circuit to the first integrated circuit, wherein the first integrated circuit, the second integrated circuit, and a third integrated circuit are mounted on the support device, and wherein the third integrated circuit is in between the first integrated circuit and the second integrated circuit in a circuit system.

In Example 10, the method of Example 9 further comprises: transmitting a third signal through a second interconnection conductor in the support device from a fourth integrated circuit to a fifth integrated circuit; and transmitting a fourth signal through the second interconnection conductor from the fifth integrated circuit to the fourth integrated circuit, wherein the fourth integrated circuit, the fifth integrated circuit, and a sixth integrated circuit are mounted on the support device, and wherein the sixth integrated circuit is in between the fourth integrated circuit and the fifth integrated circuit in the circuit system.

In Example 11, the method of any one of Examples 9-10 may optionally include, wherein the support device comprises an interposer.

In Example 12, the method of any one of Examples 9-11 may optionally include, wherein the support device comprises a package substrate.

In Example 13, the method of any one of Examples 9-12 may optionally include, wherein a fourth integrated circuit is mounted on the support device, and wherein the fourth integrated circuit is in between the first integrated circuit and the second integrated circuit.

In Example 14, the method of any one of Examples 9-13 may optionally include, wherein the first interconnection conductor comprises a right angle turn in a top down perspective of the circuit system.

In Example 15, the method of any one of Examples 9-14 may optionally include, wherein the first interconnection conductor is routed diagonally with respect to an edge of the support device.

Example 16 is an integrated circuit package comprising: an interconnection device comprising a first conductor; and first, second, and third integrated circuit dies that are coupled to the interconnection device, wherein the first integrated circuit die is coupled to the third integrated circuit die through the first conductor, and wherein the first conductor is routed under the second integrated circuit die between the first integrated circuit die and the third integrated circuit die.

In Example 17, the integrated circuit package of Example 16 further comprises: fourth, fifth, and sixth integrated circuit dies that are coupled to the interconnection device, wherein the fourth integrated circuit die is coupled to the fifth integrated circuit die through a second conductor in the interconnection device, and wherein the second conductor is routed under the sixth integrated circuit die between the fourth integrated circuit die and the fifth integrated circuit die.

In Example 18, the integrated circuit package of any one of Examples 16-17 may optionally include, wherein the interconnection device is an interposer.

In Example 19, the integrated circuit package of any one of Examples 16-17 may optionally include, wherein the interconnection device is a package substrate.

In Example 20, the integrated circuit package of any one of Examples 16-19 may optionally include, wherein the first conductor comprises at least one right angle turn in a top down view of the integrated circuit package.

The foregoing description of the examples has been presented for the purpose of illustration. The foregoing description is not intended to be exhaustive or to be limiting to the examples disclosed herein. In some instances, features of the examples can be employed without a corresponding use of other features as set forth. Many modifications, substitutions, and variations are possible in light of the above teachings.

1. A circuit system comprising:
a support device comprising a first interconnection conductor; and
first, second, and third integrated circuits that are coupled to the support device, wherein the first interconnection conductor couples the first integrated circuit to the third integrated circuit, and wherein the second integrated circuit is between the first integrated circuit and the third integrated circuit.

2. The circuit system of claim 1 further comprising:
fourth and fifth integrated circuits that are coupled to the support device, wherein the support device further comprises a second interconnection conductor that couples the first integrated circuit to the fifth integrated circuit, and wherein the fourth integrated circuit is between the first integrated circuit and the fifth integrated circuit.

3. The circuit system of claim 1, wherein the support device comprises an interposer.

4. The circuit system of claim 1, wherein the circuit system is an integrated circuit package, and wherein the support device comprises a package substrate.

5. The circuit system of claim 1, wherein the first interconnection conductor comprises a first portion that is routed at a right angle with respect to a second portion of the first interconnection conductor from a top down perspective of the circuit system.

6. The circuit system of claim 1, wherein the first interconnection conductor is routed diagonally with respect to an edge of the support device.

7. The circuit system of claim 1, wherein the first integrated circuit and the third integrated circuit are in two corners of an array of dies in the circuit system, and wherein the first interconnection conductor is at least part of a corner-to-corner connection between the first integrated circuit and the third integrated circuit.

8. The circuit system of claim 1 further comprising:
a fourth integrated circuit mounted on the support device, wherein the first integrated circuit is vertically mounted above the fourth integrated circuit; and
a fifth integrated circuit mounted on the support device, wherein the third integrated circuit is vertically mounted above the fifth integrated circuit.

9. A method comprising:
transmitting a first signal through a first interconnection conductor in a support device from a first integrated circuit to a second integrated circuit; and
transmitting a second signal through the first interconnection conductor from the second integrated circuit to the first integrated circuit,
wherein the first integrated circuit, the second integrated circuit, and a third integrated circuit are mounted on the support device, and wherein the third integrated circuit is in between the first integrated circuit and the second integrated circuit in a circuit system.

10. The method of claim 9 further comprising:
transmitting a third signal through a second interconnection conductor in the support device from a fourth integrated circuit to a fifth integrated circuit; and
transmitting a fourth signal through the second interconnection conductor from the fifth integrated circuit to the fourth integrated circuit,
wherein the fourth integrated circuit, the fifth integrated circuit, and a sixth integrated circuit are mounted on the support device, and wherein the sixth integrated circuit is in between the fourth integrated circuit and the fifth integrated circuit in the circuit system.

11. The method of claim 9, wherein the support device comprises an interposer.

12. The method of claim 9, wherein the support device comprises a package substrate.

13. The method of claim 9, wherein a fourth integrated circuit is mounted on the support device, and wherein the fourth integrated circuit is in between the first integrated circuit and the second integrated circuit.

14. The method of claim 9, wherein the first interconnection conductor comprises a right angle turn in a top down perspective of the circuit system.

15. The method of claim 9, wherein the first interconnection conductor is routed diagonally with respect to an edge of the support device.

16. An integrated circuit package comprising:
an interconnection device comprising a first conductor; and
first, second, and third integrated circuit dies that are coupled to the interconnection device, wherein the first integrated circuit die is coupled to the third integrated circuit die through the first conductor, and wherein the first conductor is routed under the second integrated circuit die between the first integrated circuit die and the third integrated circuit die.

17. The integrated circuit package of claim 16 further comprising:
fourth, fifth, and sixth integrated circuit dies that are coupled to the interconnection device, wherein the fourth integrated circuit die is coupled to the fifth integrated circuit die through a second conductor in the interconnection device, and wherein the second conductor is routed under the sixth integrated circuit die between the fourth integrated circuit die and the fifth integrated circuit die.

18. The integrated circuit package of claim 16, wherein the interconnection device is an interposer.

19. The integrated circuit package of claim 16, wherein the interconnection device is a package substrate.

20. The integrated circuit package of claim 16, wherein the first conductor comprises at least one right angle turn in a top down view of the integrated circuit package.
